(19) United States
(12) Patent Application Publication
(10) Pub. No.: US 2025/0233560 A1
(43) Pub. Date: Jul. 17, 2025

(54) LOAD MODULATED POWER AMPLIFIER SYSTEM WITH PHASE COMPENSATION

(71) Applicant: Skyworks Solutions, Inc., Irvine, CA (US)

(72) Inventors: Serge Francois Drogi, Flagstaff, AZ (US); Philip John Lehtola, Cedar Rapids, IA (US)

(21) Appl. No.: 19/017,210

(22) Filed: Jan. 10, 2025

Related U.S. Application Data
(60) Provisional application No. 63/621,103, filed on Jan. 15, 2024.

(51) Int. Cl. H03F 1/32; H03F 3/24

(52) U.S. Cl. CPC H03F 1/3241; H03F 3/245; H03F 2200/105; H03F 2200/451

(57) ABSTRACT

A mobile device includes a baseband processor configured to provide a modulated digital signal and one or more processors configured to apply digital pre-distortion and phase compensation to the modulated digital signal to generate a compensated digital signal. A radio frequency modulator converts the compensated digital signal to a radio frequency signal, and a load modulated power amplifier amplifies the radio frequency signal.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to electronic systems, and in particular, to radio frequency (RF) electronics.

### Description of the Related Technology

Power amplifiers are used in RF communication systems to amplify RF signals for transmission via antennas.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. RF signals have a frequency in the range from about 30 kHz to 300 GHz, for instance, in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

### SUMMARY

In some aspects, the techniques described herein relate to a mobile device including: a baseband processor configured to provide a modulated digital signal; one or more processors configured to apply digital pre-distortion and phase compensation to the modulated digital signal to generate a compensated digital signal; a radio frequency modulator configured to convert the compensated digital signal to a radio frequency signal; and a load modulated power amplifier configured to amplify the radio frequency signal.

In some aspects, the techniques described herein relate to a mobile device wherein the digital pre-distortion is based at least in part on a feedback signal corresponding to the amplified radio frequency signal.

In some aspects, the techniques described herein relate to a mobile device wherein the phase compensation is applied following the digital pre-distortion.

In some aspects, the techniques described herein relate to a mobile device further including a memory storing values used by the one or more processors to control the phase compensation.

In some aspects, the techniques described herein relate to a mobile device wherein the load modulated power amplifier includes a controllable load impedance coupled to an output of the load modulated power amplifier, the controllable load impedance adjustable via a load modulation control signal.

In some aspects, the techniques described herein relate to a mobile device wherein the controllable load impedance includes a controllable capacitor controlled by the load modulation control signal and an output balun having a first winding coupled to the output of the load modulated power amplifier and a second winding coupled to the controllable capacitor.

In some aspects, the techniques described herein relate to a mobile device wherein the load modulation control signal includes an envelope signal.

In some aspects, the techniques described herein relate to a mobile device further including a shaping circuit configured to shape the envelope signal based on calibration data.

In some aspects, the techniques described herein relate to a mobile device wherein the shaping circuit is operable to provide a flat gain versus input power characteristic to the load modulated power amplifier.

In some aspects, the techniques described herein relate to a mobile device further including an antenna operable to transmit the amplified radio frequency signal.

In some aspects, the techniques described herein relate to a load modulated power amplifier system including: one or more processors configured to apply digital pre-distortion and phase compensation to modulated digital signals to generate a compensated digital signal; a radio frequency modulator configured to convert the compensated digital signal to a radio frequency signal; a load modulated power amplifier configured to receive a radio frequency signal and provide an amplified radio frequency signal.

In some aspects, the techniques described herein relate to a load modulated power amplifier system wherein the digital pre-distortion is based at least in part on a feedback signal corresponding to the amplified radio frequency signal.

In some aspects, the techniques described herein relate to a load modulated power amplifier system wherein the phase compensation is applied following the digital pre-distortion.

In some aspects, the techniques described herein relate to a load modulated power amplifier system further including a memory storing values used by the one or more processors to control the phase compensation.

In some aspects, the techniques described herein relate to a load modulated power amplifier system wherein the load modulated power amplifier includes a controllable load impedance coupled to an output of the load modulated power amplifier, the controllable load impedance adjustable via a load modulation control signal.

In some aspects, the techniques described herein relate to a load modulated power amplifier system wherein the controllable load impedance includes a controllable capacitor controlled by the load modulation control signal and an output balun having a first winding coupled to the output and a second winding coupled to the controllable capacitor.

In some aspects, the techniques described herein relate to a load modulated power amplifier system wherein the load modulation control signal includes an envelope signal.

In some aspects, the techniques described herein relate to a load modulated power amplifier system further including a shaping circuit configured to shape the envelope signal based on calibration data.

In some aspects, the techniques described herein relate to a load modulated power amplifier system wherein the shaping circuit is operable to provide a flat gain versus input power characteristic to the load modulated power amplifier.

In some aspects, the techniques described herein relate to a load modulated power amplifier system further including an antenna operable to transmit the amplified radio frequency signal.

In some aspects, the techniques described herein relate to a method of amplification in a mobile device, the method including: with one or more processors, applying digital pre-distortion and phase compensation to a modulated digital signal; converting the digitally pre-distorted and phase compensated digital signal to a radio frequency signal; and amplifying the radio frequency signal with a load modulated power amplifier to generate a load modulated amplified radio frequency signal.

In some aspects, the techniques described herein relate to a method further including using values accessed from a lookup table in memory to control the phase compensation.

In some aspects, the techniques described herein relate to a method further including adjusting a controllable load impedance coupled to an output of the load modulated power amplifier.

In some aspects, the techniques described herein relate to a method further including receiving a feedback signal corresponding to the load modulated amplified radio frequency signal, and applying the digital pre-distortion based on at least the feedback signal.

In some aspects, the techniques described herein relate to a method wherein the phase compensation is applied after the digital pre-distortion.

### BRIEF DESCRIPTION OF THE DRAWINGS

Embodiments of this disclosure will now be described, by way of non-limiting example, with reference to the accompanying drawings.

FIG. 1 is a schematic diagram of one embodiment of a load modulated power amplifier.

FIG. 2 is a schematic diagram of another embodiment of a load modulated power amplifier.

FIG. 3 is a schematic diagram of one embodiment of a load modulated power amplifier system.

FIG. 4A is a schematic diagram of another embodiment of a load modulated power amplifier system.

FIG. 4B is a schematic diagram of another embodiment of a load modulated power amplifier system.

FIG. 5 shows a diagram of an embodiment of a load modulated power amplifier system with digital pre-distortion to correct for both AM/PM of the power amplifier and AM/PM added via the load modulation.

FIG. 6A shows a diagram of an embodiment of a load modulated power amplifier system with a phase modulator used to correct for phase modulation added via the load modulation.

FIG. 6B shows an example of a phase modulator that can be included in a system such as the one of FIG. 6A.

FIG. 7A is an example of a plot showing uncompensated AM/PM response as seen at an output of a load modulation power amplifier.

FIG. 7B is an example of a graph showing a comparison of plots of AM/PM response without phase compensation, with phase compensation using a linear fit phase compensation lookup table, and after phase compensation.

FIG. 7C is an example of a plot showing AM/PM error before phase compensation and digital pre-distortion.

FIG. 7D is an example of a plot showing AM/PM error after phase compensation but before digital pre-distortion.

FIG. 8 is an example of a graph showing spectral improvement achieved using digital phase compensation.

FIG. 9 is a schematic diagram of another embodiment of a communication system for transmitting load-modulated RF signals using phase compensation.

FIG. 10A is a schematic diagram of one embodiment of a controllable capacitor for a load modulated power amplifier.

FIG. 10B is a schematic diagram of another embodiment of a controllable capacitor for a load modulated power amplifier.

FIG. 11 is a schematic diagram of one embodiment of a mobile device.

FIG. 12A is a schematic diagram of one embodiment of a packaged module.

FIG. 12B is a schematic diagram of a cross-section of the packaged module of FIG. 12A taken along the lines 12B-12B.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Load modulated power amplifiers are provided herein. In certain embodiments, a load modulated power amplifier includes a power amplifier that amplifies a radio frequency (RF) input signal, and a load impedance coupled to an output of the power amplifier. For example, the load impedance can be controlled based on an envelope of the RF input signal to provide load modulation to the output of the power amplifier. Providing load impedance modulation in this manner provides high efficiency over a wide dynamic range. For example, high efficiency power amplifiers can be load modulated to enhance their efficiency with a non-zero peak to average modulated signal. The load modulator can be controlled externally by a digital baseband which synchronizes and scales the load modulation signal before applying the electrical signal to the modulator.

In certain implementations, the load impedance includes a heterojunction bipolar transistor (HBT) switch having a collector coupled to a capacitor and a base controlled by the envelope signal. Additionally, the HBT switch operates as a variable resistor with the highest load line achieved when the switch is open and with the lowest load line achieved at the highest envelope voltage level when the switch is closed. In such a configuration, the lowest loss is achieved at the highest load line, which is beneficial for modulated efficiency of a high peak-to-average power ratio (PAPR) waveform, such as those used in 5G communications.

In comparison to power amplifiers in which an envelope tracker controls a supply voltage of the power amplifier based on an envelope signal, the load modulated power amplifier has a load impedance controlled based on the envelope signal. Providing load modulation in this manner provides higher efficiency power amplifiers that are less complex than envelope tracking amplifiers, while leveraging circuitry for generating and calibrating the envelope signal for desired performance.

For example, a load modulated power amplifier can be powered by a high efficiency DC-to-DC converter, for instance, a power management unit (PMU) operating with an efficiency of 93% or higher. Such a PMU can, for instance, operate using average power tracking (APT) over 5.5V+2.5-3.0V (power amplifier efficiency can be better at higher supply voltage due to non-zero knee voltage). In contrast, an envelope tracking system may have only 80% efficiency, with the supply voltage ˜2.5-3.0V (power amplifier efficiency can be worse at lower supply voltage due to non-zero knee voltage). A PMU is also referred to herein as a power management integrated circuit (PMIC).

Load modulated power amplifiers can be included in a wide variety of RF communication systems, including, but not limited to, base stations, network access points, mobile phones, tablets, customer-premises equipment (CPE), laptops, computers, wearable electronics, and/or other communication devices.

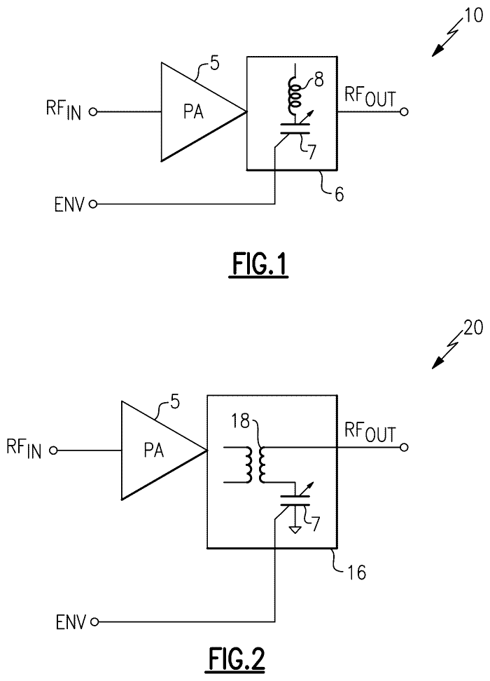

FIG. 1 is a schematic diagram of one embodiment of a load modulated power amplifier 10. The load modulated power amplifier 10 includes a power amplifier 5 and a controllable load impedance 6. The load modulated power amplifier 10 amplifies an RF input signal RF_{IN} to generate an RF output signal RF_{OUT}.

The load modulated power amplifier 10 receives an envelope signal ENV that changes in relation to an envelope of the RF input signal RF_{IN}. The envelope signal ENV is used to control an impedance of the controllable load impedance 6. For example, in this embodiment, the controllable load impedance 6 includes a series combination of an inductor 8 and a controllable capacitor 7, and the envelope signal ENV is used to control a capacitance of the controllable capacitor 7. Although one example of a controllable load impedance is depicted, the teachings herein are applicable to other implementations of controllable load impedances.

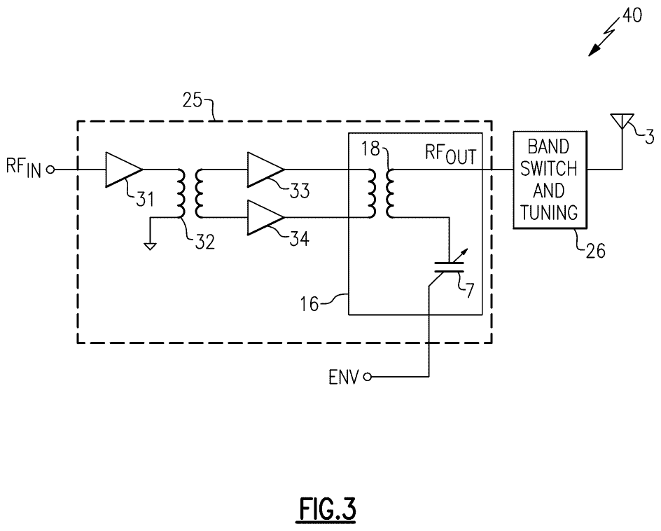

FIG. 2 is a schematic diagram of another embodiment of a load modulated power amplifier 20. The load modulated power amplifier 20 of FIG. 2 is similar to the load modulated power amplifier 10 of FIG. 1, except that the load modulated power amplifier 20 of FIG. 2 includes a different implementation of a controllable load impedance 16.

In particular, the controllable load impedance 16 includes a balun 18 and a controllable capacitor 7. An output of the power amplifier 5 drives a first winding of the balun 18. Additionally, a first terminal of a second winding of the balun 18 outputs the RF output signal RF_{OUT}, while a second terminal of the second winding is coupled to the controllable capacitor 7. The controllable capacitor 7 is controlled by the envelope signal ENV.

Changing a value of the controllable capacitor 7 effectively resonates out some of the inductance of the second winding, thereby effectively changing a turn ratio of the balun 18.

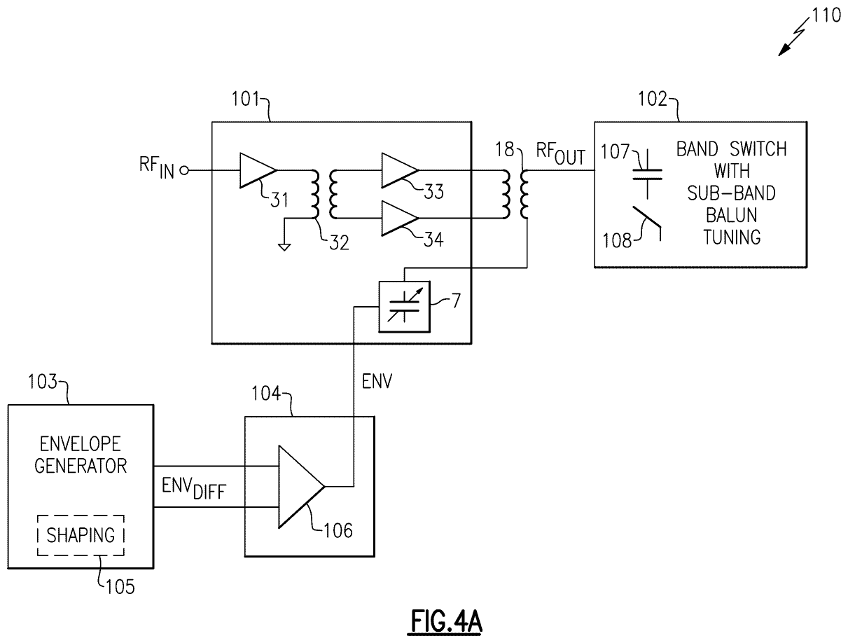

FIG. 3 is a schematic diagram of one embodiment of a load modulated power amplifier system 40. The load modulated power amplifier system 40 includes a load modulated power amplifier 25, a band switching and tuning circuit 26, and an antenna 3.

In the illustrated embodiment, the load modulated power amplifier 25 includes a driver amplifier 31, an input balun 32, a first output amplifier 33, a second output amplifier 34, and a controllable load impedance 16 that includes an output balun 18 and a controllable capacitor 7.

The load modulated power amplifier 25 is implemented as a push-pull amplifier, in this embodiment. Additionally, an output of the first output amplifier 33 is connected to a first terminal of a first winding of the balun 18, while an output of the second output amplifier 34 is connected to a second terminal of the first winding of the balun 18.

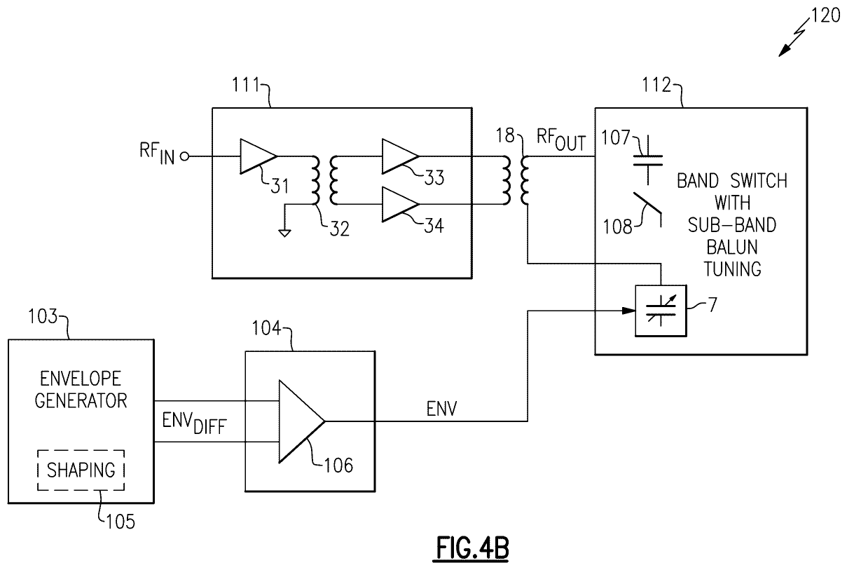

FIG. 4A is a schematic diagram of another embodiment of a load modulated power amplifier system 110. The load modulated power amplifier system 110 includes an output balun 18, a power amplifier die 101, a switch die 102, an envelope generator die 103, and a driver die 104. The power amplifier die 101 includes a driver amplifier 31, an input balun 32, a first output amplifier 33, a second output amplifier 34, and a controllable capacitor 7. The switch die 102 includes a capacitor 107 and a switch 108. Furthermore, the envelope generator die 103 includes a shaping circuit 105 for shaping a differential envelope signal ENV_{DIFF} provided to the driver die 104. The driver die 104 includes an amplifier 106 for receiving the differential envelope signal ENV_{DIFF}, and that outputs an envelope control signal ENV for controlling the controllable capacitor 7.

The load modulated power amplifier system 110 can operate with system level calibration for aligning and shaping the envelope control signal for the controllable capacitor 7 to the RF input signal amplified by the push-pull amplifier.

FIG. 4B is a schematic diagram of another embodiment of a load modulated power amplifier system 120. The load modulated power amplifier system 120 includes an output balun 18, a power amplifier die 111, a switch die 112, an envelope generator die 103, and a driver die 104.

The load modulated power amplifier system 120 of FIG. 4B is similar to the load modulated power amplifier system 110 of FIG. 4A, except that the load modulated power amplifier system 120 illustrates an implementation in which the controllable capacitor 7 is on the switch die 112. Since the switch die 112 is typically implemented using a silicon on insulator (SOI) process and the power amplifier die 111 using a compound semiconductor process (for instance, GaAs), placing the controllable capacitor 7 on the switch die 112 aids in providing a high quality factor (Q-factor) capacitor.

Thus, the output of the power amplifier 111 can be coupled to a first terminal of the first winding of the output balun 18 (or in a push-pull configuration with outputs coupled to two terminals of the first winding), while an amplified RF signal is outputted from a first terminal of the second winding of the output balun. The load impedance further can further include the controllable capacitor 7 coupled to a second terminal of the second winding and having a capacitance controlled by the envelope of the RF signal.

Load modulation in certain embodiments can be performed by sweeping an impedance of a termination capacitor 7 on the secondary port of a balun 18. In certain implementations, the termination capacitor 7 is controlled by an analog control signal from a transceiver, such as an envelope signal ENV, which can be calibrated to achieve desired gain and/or efficiency characteristics, such as isogain.

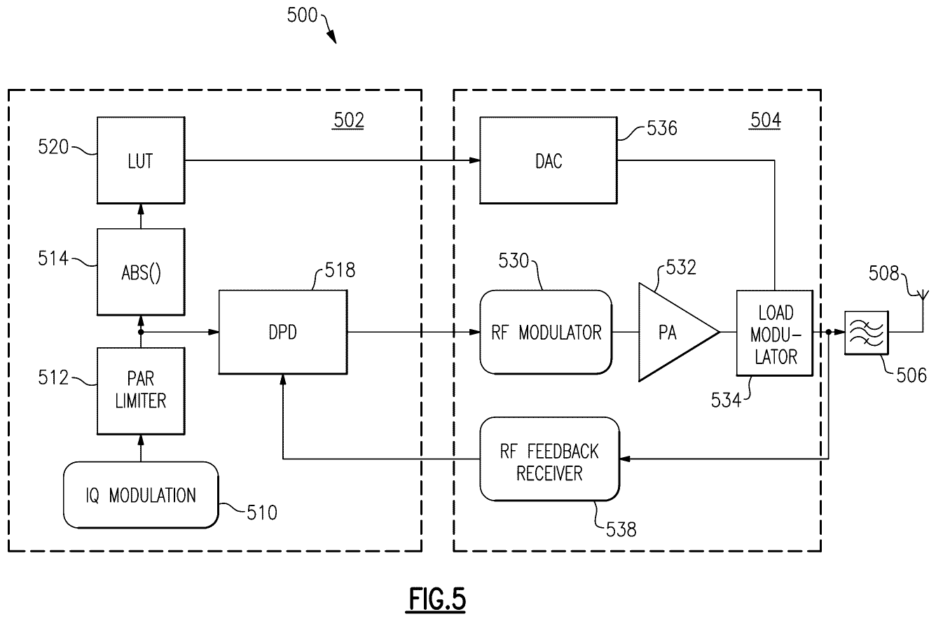

FIG. 5 shows a diagram of an embodiment of a load-modulated power amplifier system 500 with digital pre-distortion to correct for both AM/PM of the power amplifier and AM/PM added via the load modulation.

The illustrated system 500 includes a first group of components 502, a second group of components 504, and one or more filtering, switching, and/or multiplexing components 506 for connecting the power amplifier system 500 to at least one antenna 508.

According to certain embodiments, the first group of components 502 can be implemented in firmware or software, such as in one or more processors of a transceiver and/or baseband processor, whereas the second group of components 504 can be implemented in hardware, such as in a transceiver and/or front end modules.

The first group of components 502 includes an IQ modulation generator 510, which can generate digital I and Q signals corresponding to signal components of a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave.

The IQ modulator generator can output the I and Q signals to a peak-average-ratio (PAR) limiter 512, which outputs PAR limited digital I/Q digital signals to a digital pre-distorter (DPD) and an absolute value block 514 (Abs[ ]).

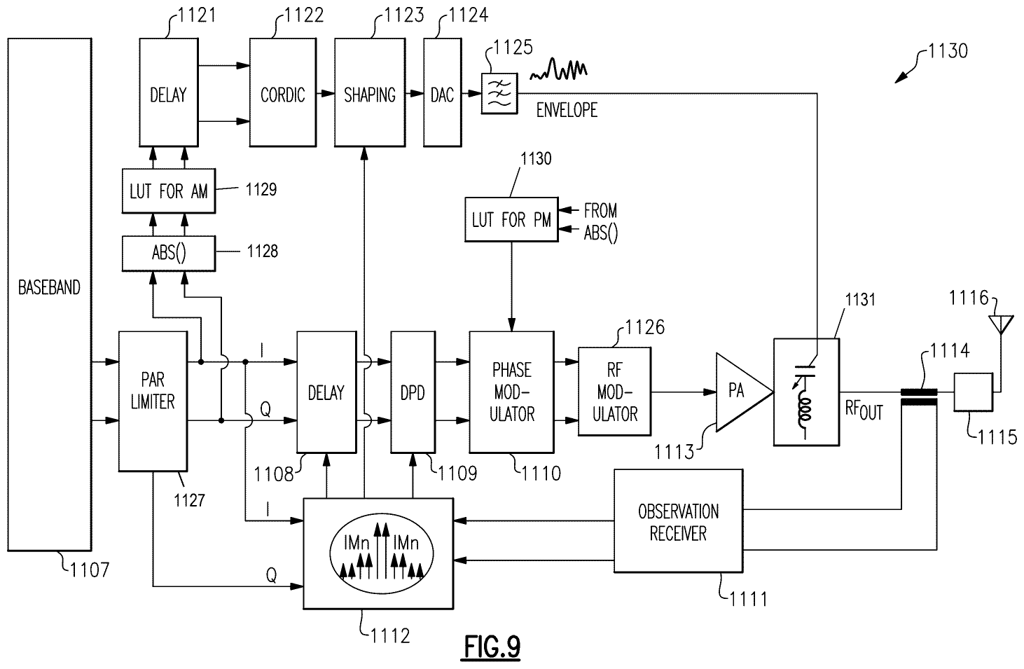

The DPD 518 can be configured to provide digital shaping processed I and Q signals to generate digitally pre-distorted I and Q signals. For example, the pre-distortion can be controlled based on amount of intermodulation detected by an intermodulation detection circuit by the RF feedback receiver 538 residing in the second group of components 504. In another embodiment, the amount of intermodulation can be detected by a component implemented in software or firmware. The RF feedback receiver 538 may include or be similar to the observation receiver 1111 and/or the intermodulation detector 1112 of FIG. 9, for example. In other embodiments, some or all of the RF feedback receiver 538 may be included in the first group of components 502 instead of the second group of components 504.

The DPD 518 can serve to reduce a distortion of the PA and/or to increase the efficiency of the PA. A delay function and/or other functions can be applied prior to the DPD, depending on the embodiment.

The absolute value block can output the absolute value of the PAR limited I/Q signals to a lookup-table (LUT) 520, which can include a set of adapting or fixed values stored in a table in memory. The values output by the LUT can be configured to adjust a signal for load-modulating the power amplifier output.

The second ds 504 includes a radio frequency (RF) modulator 530, which can convert the digitally pre-distorted digital I/Q signals into an analog RF input, which the RF modulator 530 provides to an input of a power amplifier (PA) 532. The output of the PA 532 includes or is coupled to a load modulator 534 configured to modulate the PA load. The load modulator 534 can be similar to any of the load modulators described herein, e.g., with respect to FIG. 1-4B or 9-10B, or can be some other type of load modulator.

The second group of components 504 further includes a digital to analog converter (DAC) 536 which receives digital values from the LUT 520. The DAC 536 converts the digital values to a corresponding analog signal which the DAC 536 provides as a control input to the load modulator 534. While not illustrated in FIG. 5 for the purposes of simplicity, additional functions can be implemented before DAC 536 such as a delay, shaping, a coordinate rotation digital computation (CORDIC) function, some of which can be implemented by the LUT, for example.

The modification of the load transformation at the output of the PA 532 by the load modulator 534 can introduce undesirable AM/PM (amplitude-to-phase) modulation or response variation. Moreover, such phase modulation can have the effect of broadening the power amplifier output spectrum, resulting in reduced or limited out of band and spectral emission performance.

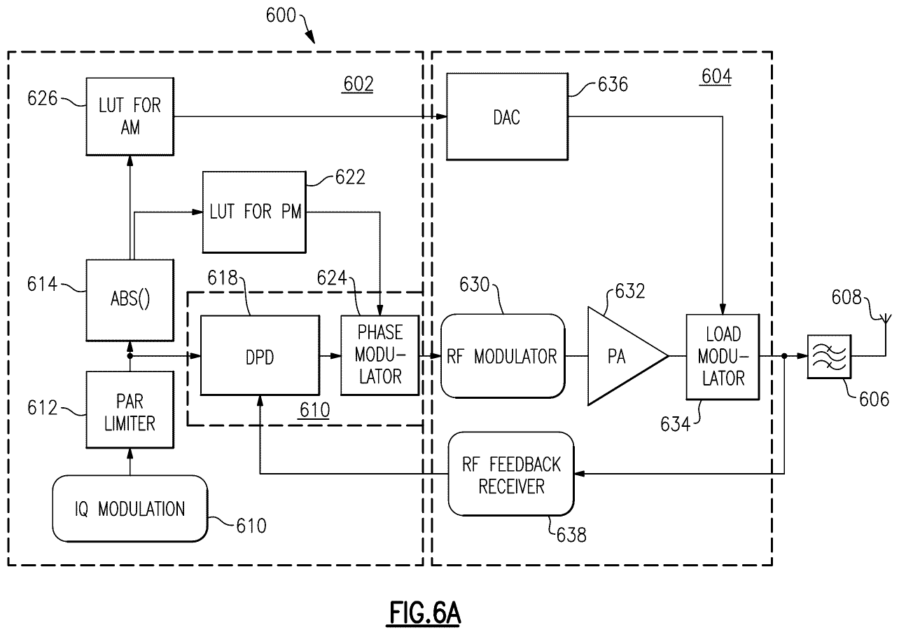

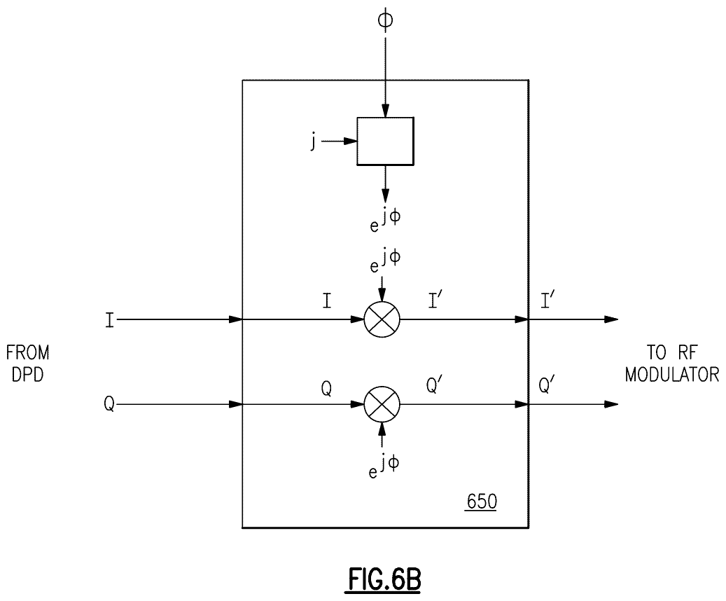

FIG. 6A illustrates an embodiment of a load modulated power amplifier system 600 with a phase modulator used to correct or compensate for phase modulation added via the power amplifier load modulation. The phase modulator is also referred to herein as a phase compensator.

As shown, the power amplifier system 600 includes a first group of components 602 and a second group of components 604. Like the system of FIG. 5, the first group of components 602 can be implemented in firmware or software, such as in one or more processors of a transceiver and/or baseband processor, whereas the second group of components 604 can be implemented in hardware, such as in circuitry of one or more transceivers and/or front end modules. Moreover, like the system 500 of FIG. 5, the system 600 includes one or more filtering, switching, and/or multiplexing components 606 for connecting the power amplifier system 600 to at least one antenna 608.

The second group of components 604 can be similar to or the same as the similarly named components in the second group of components 504 of the system 500 of FIG. 5. Likewise, the first group of components 602 can include substantially similar components as the similarly named components in the first group of components 502 of the system 500 of FIG. 5.

However, in contrast to the system 500 of FIG. 5, the first group of components 602 additionally includes a lookup table for phase modulation 622 (LUT for PM) and a phase modulator 624 (which can alternatively be referred to as a phase compensator) between the DPD 618 and the RF modulator 630. In addition, a lookup table for amplitude modulation 626 (LUT for AM) is connected to the DAC and can include a set of adapting or fixed values stored in a table in memory. The values output by the LUT for AM 626 can be configured to adjust a signal for load-modulating the power amplifier output with respect to amplitude.

The LUT for PM 622 can include a set of adapting or fixed values stored in a table in memory for controlling the phase modulator 624. The phase modulator 624 can be configured to adjust the digital signal received from the DPD 618 to compensate for AM/PM response variations caused by the load modulator 634. For instance, the phase modulator 624 can be configured to, based on the values received from the LUT for PM 622, adjust the I/Q signals received from the DPD to correct for AM/PM phase modulation introduced by the load modulator.

FIG. 6B shows one example of a phase modulator 650. For example, the phase modulator 624 of FIG. 6A may be the same as the phase modulator 650 of FIG. 6B according to some embodiments. As shown, the phase modulator 650 receives an I value and a Q value from the DPD 618, where the I and Q values are a complex representation of the RF signal. The phase modulator 650 comprises software, firmware, and/or hardware that computes the complex mathematic function e^{(jφ)}, where φ can be the value provided by the LUT for PM 622. The phase modulator 650 further comprises software, firmware, and/or hardware that multiplies the I value and the Q value by the calculated value, e^{(jφ)}, to generate I′ and Q′, respectively, which are phase adjusted versions of the I and Q signals. φ can be relatively small, and the phase modulator 650 in some cases calculates an approximation of e^{(jφ)} that is sufficiently precise for relatively small values of q. Calculation of an approximation can be more straightforward and less resource or time intensive to compute in the digital domain than an exact calculation of the function e^{(jφ)}. In other embodiments, the phase modulator 650 performs an exact calculation.

The inclusion of the phase modulator 624 in the system 600 of FIG. 6A can be configured to provide digital phase compensation to significantly reduce spectral regrowth while allowing the use of a reduced complexity DPD algorithm to fine tune the spectral correction. By removing or reducing most or a substantial part of the phase modulation with a compensation calculated, and therefore synchronized, with the load modulation, the first order effect of phase modulation with load modulation can be greatly reduced or eliminated, resulting in a much more linear response in phase modulation of the signal seen by the DPD loop compensation.

According to certain embodiments, the IQ modulation block can be included in a baseband processor, some or all of the DPD, phase modulator, LUT for AM and LUT for PM, and RF modulator, and DAC can be included on a radio frequency transceiver, and some or all of the PA, load modulator, switches, filters, and multiplexers 606 can be included on one or more front end modules, although a variety of implementations are possible.

The AM/PM versus load modulation can be quite linear with load control voltage, but very non-linear with respect to the RF input amplitude. The signal used to load modulate is therefore an ideal driver for phase compensating the RF signal.

In contrast to the system 600 of FIG. 6A, in the system 500 of FIG. 5, the DPD loop attempts to correct for both AM/PM of the power amplifier and the AM/PM added by the load modulator, which can result in a more non-linear response of the phase modulation versus RF. In the system 600 of FIG. 6A, on the other hand, the phase modulator corrects the phase modulation added by the load modulator, resulting in a more linear AM/PM response seen by the DPD loop. A more linearized AM/PM response versus RF around the DPD loop, enabling more straightforward correction.

Moreover, the system of FIG. 6A can provide phase compensation in the digital domain as opposed to in an analog domain, which can provide advantages including case of implementation, software-based control, enabling of timing and delays to be controlled by finer timing alignment of phase and effective load modulation, and reduced cost.

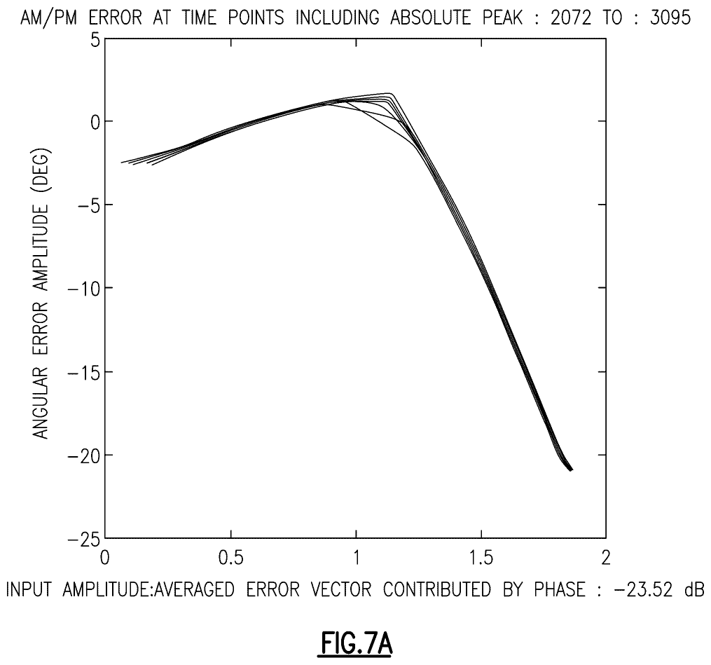

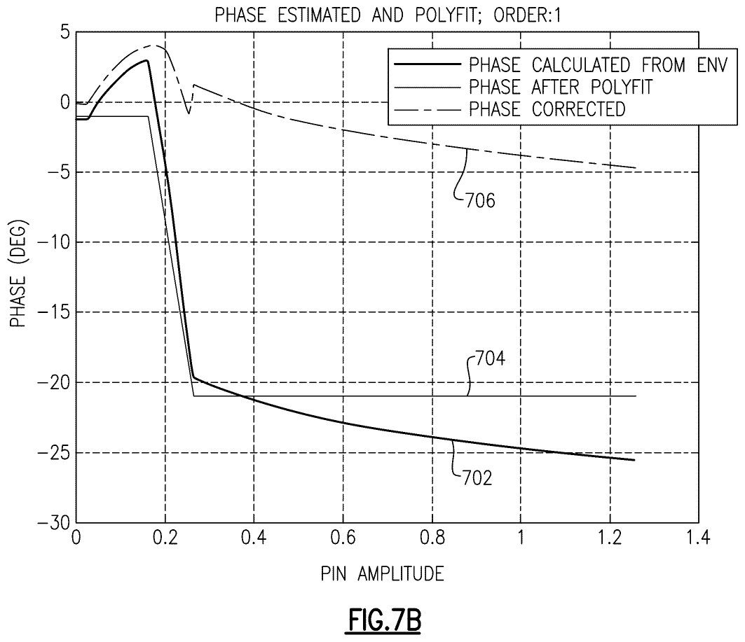

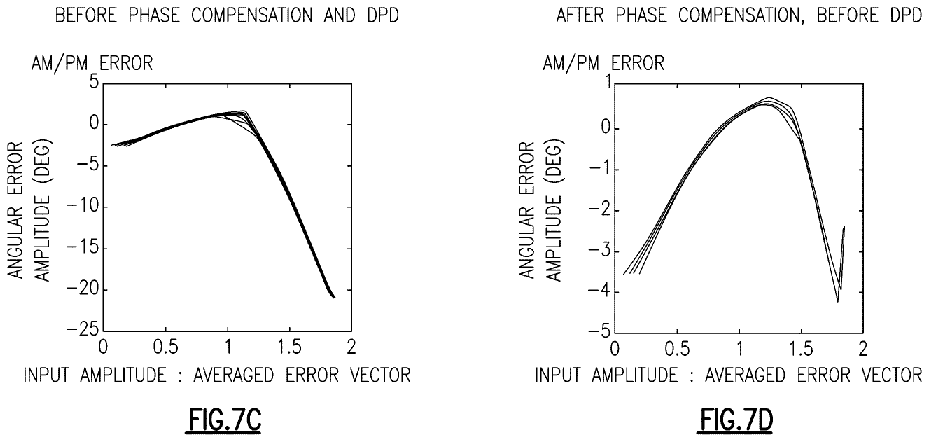

FIG. 7A is an example of a plot showing uncompensated AM/PM response as seen at an output of a load modulation power amplifier.

FIG. 7B is an example of a graph showing a comparison of plots of AM/PM response (phase noise) without phase compensation (702), a linear fit (704) to the undesired phase noise, which can be stored in a phase compensation lookup table, and phase response (706) after compensation, which can be referred to as residual or remaining phase noise.

The first plot 702 shows that uncompensated AM/PM response versus RF is quite non-linear, making it challenging to fit with a low order polynomial. Such undesired AM/PM phase noise can be the result of a load modulation architecture such as the one shown in FIG. 4B. For instance, changing capacitance as a function of the envelope signal can provide desirable load modulation but also detune the inductor-capacitor network at the output of the power amplifier, resulting in undesired AM/PM phase noise.

The second plot 704 shows AM/PM versus RF after a linear fit versus the load modulator control voltage, where the linear fit can be stored in a phase compensation look-up table. For example, the curve 704 can be a linear fit to the undesired phase noise represented in the first plot 702. As an example, referring to FIG. 6A, the curve 704 can be implemented and stored in the LUT for PM 622. In some embodiments, the linear fit 704 can be represented as a four point table corresponding to the four coordinates of the linear fit 704.

The third plot 706 shows AM/PM versus RF phase response after compensation using a phase modulator, such as the phase modulator 624 of the system 600 of FIG. 6A or the phase modulator 650 of FIG. 6B. The curve 706 can represent the difference between the first plot 702 (uncompensated phase noise) and the second plot 704 (linear fit to the phase noise). The resulting smaller residual phase versus RF input level can enable more straightforward reduction to acceptable or target phase noise levels, e.g., using a low order polynomial fit in the DPD loop. As such, the DPD can readily compensate for the relatively small amount of remaining residual phase noise.

FIG. 7C is an example of a plot showing AM/PM error before phase compensation and digital pre-distortion. FIG. 7D is an example of a plot showing AM/PM error after phase compensation, but before digital pre-distortion. As shown, the AM/PM amplitude is reduced from 23 degrees peak-to-peak in FIG. 7C to less than 5 degrees peak-to-peak in FIG. 7D, which can provide for more effective and straightforward DPD processing.

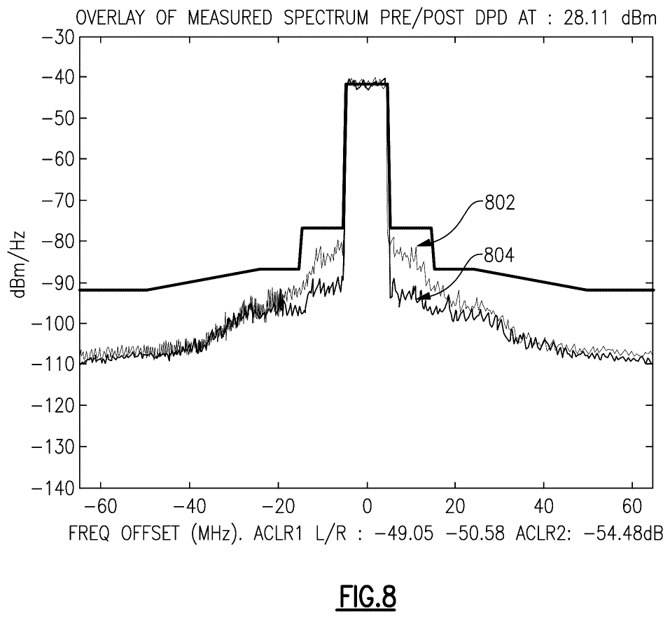

FIG. 8 is an example of a graph showing spectral improvement achieved using digital phase compensation for a New Radio (NR) radio cellular system. The plot 802 shows the measured spectrum with DPD but without phase compensation. The plot 804 shows the measured spectrum with DPD and with phase compensation enabled (with 2 DPD cycles shown). This shows a clear improvement with phase compensation, in both the spectral mask and out of band performance.

FIG. 9 is a schematic diagram of one embodiment of a communication system 1130 for transmitting load-modulated RF signals using phase compensation with a phase modulator 1110. The system 1130 can operate similarly to the system 600 of FIG. 6A, for example.

The communication system 1130 includes a baseband processor 1107, a signal delay circuit 1108, a digital pre-distortion (DPD) circuit 1109, an I/Q modulator 1110, an observation receiver 1111, an intermodulation detection circuit 1112, a power amplifier 1113, a directional coupler 1114, a duplexing and switching circuit 1115, an antenna 1116, an envelope delay circuit 1121, a coordinate rotation digital computation (CORDIC) circuit 1122, a shaping circuit 1123, a digital-to-analog converter 1124, and a reconstruction filter 1125.

The baseband processor 1107 operates to generate an I signal and a Q signal, which correspond to signal components of a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals are provided to the I/Q modulator 1110 in a digital format. The baseband processor 1107 can be any suitable processor configured to process a baseband signal. For instance, the baseband processor 1107 can include a digital signal processor, a microprocessor, a programmable core, or any combination thereof.

The signal delay circuit 1108 provides adjustable delay to the I and Q signals to aid in controlling relative alignment between the envelope signal and the RF signal RF_{IN}. The amount of delay provided by the signal delay circuit 1108 is controlled based on amount of intermodulation detected by the intermodulation detection circuit 1112.

The DPD circuit 1109 operates to provide digital shaping to the delayed I and Q signals from the signal delay circuit 1108 to generate digitally pre-distorted I and Q signals. In the illustrated embodiment, the pre-distortion provided by the DPD circuit 1109 is controlled based on amount of intermodulation detected by the intermodulation detection circuit 1112. The DPD circuit 1109 serves to reduce a distortion of the power amplifier 1113 and/or to increase the efficiency of the power amplifier 1113. According to certain embodiments, the DPD circuit 1109 can be implemented in software or firmware, which can be implemented in one or more processors of a baseband processor or a transceiver.

The phase modulator 1110 receives the digitally pre-distorted output from the DPD circuit 1109 and provides phase modulation to provide phase compensation, e.g., for AM/PM error added by the load modulation. According to certain embodiments, the phase modulator 1110 can be implemented in software or firmware, which can be implemented in one or more processors of a transceiver, RF IC, or baseband processor. For example, the phase modulator 1110 can operate like the phase modulator 624 of the system 600 of FIG. 6A or the phase modulator 650 of FIG. 6B and receive control values from a phase modulation lookup table (PM LUT). As shown, similar to the system 600 of FIG. 6A, the system 1130 can additionally include a peak-to-average-ratio (PAR) limiter 1127, an absolute value block 1128, a look-up table for amplitude modulation 1129, and a look-up table for phase modulation 1130.

The RF modulator 1126 receives the digitally pre-distorted and phase-compensated I and Q signals, which are processed to generate an analog RF signal provided to the power amplifier 1113. For example, the RF modulator 1126 can include DACs configured to convert the digitally pre-distorted I and Q signals into an analog format, mixers for upconverting the analog I and Q signals to radio frequency, and a signal combiner for combining the upconverted I and Q signals into an RF signal suitable for amplification by the power amplifier 1113. In certain implementations, the RF modulator 1126 can include one or more filters configured to filter frequency content of signals processed therein.

The envelope delay circuit 1121 delays the I and Q signals from the baseband processor 1107. Additionally, the CORDIC circuit 1122 processes the delayed I and Q signals to generate a digital envelope signal representing an envelope of the RF signal RF_{IN}. Although FIG. 9 illustrates an implementation using the CORDIC circuit 1122, an envelope signal can be obtained in other ways.

The shaping circuit 1123 operates to shape the digital envelope signal to enhance the performance of the communication system 1130. In certain implementations, the shaping circuit 1123 includes a shaping table that maps each level of the digital envelope signal to a corresponding shaped envelope signal level. Envelope shaping can aid in controlling linearity, distortion, and/or efficiency of the power amplifier 1113.

In the illustrated embodiment, the shaped envelope signal is a digital signal that is converted by the DAC 1124 to an analog envelope signal. Additionally, the analog envelope signal is filtered by the reconstruction filter 1125 to generate an envelope signal suitable for modulating a load of the power amplifier 1113. In certain implementations, the reconstruction filter 1125 includes a low pass filter. As shown, the power amplifier 1113 can include a load modulation circuit 1131 at its output, which can be any of the load modulators described herein, for example, such as any of the load modulators of FIGS. 1-6A.

With continuing reference to FIG. 9, the power amplifier 1113 receives the RF signal RF_{IN} from the RF modulator 1110 and provides an amplified RF signal RF_{OUT} to the antenna 1116 through the duplexing and switching circuit 1115, in this example.

The directional coupler 1114 is positioned between the output of the power amplifier 1113 and the input of the duplexing and switching circuit 1115, thereby allowing a measurement of output power of the power amplifier 1113 that does not include insertion loss of the duplexing and switching circuit 1115. The sensed output signal from the directional coupler 1114 is provided to the observation receiver 1111, which can include mixers for down converting I and Q signal components of the sensed output signal, and DACs for generating I and Q observation signals from the downconverted signals.

The intermodulation detection circuit 1112 determines an intermodulation product between the I and Q observation signals and the I and Q signals from the baseband processor 1107. Additionally, the intermodulation detection circuit 1112 controls the pre-distortion provided by the DPD circuit 1109 and/or a delay of the signal delay circuit 1108 to control relative alignment between the envelope signal and the RF signal RF_{IN}. In certain implementations, the intermodulation detection circuit 1112 also serves to control shaping provided by the shaping circuit 1123.

By including a feedback path from the output of the power amplifier 1113 and baseband, the I and Q signals can be dynamically adjusted to optimize the operation of the communication system 1130. For example, configuring the communication system 1130 in this manner can aid in providing power control, compensating for transmitter impairments, and/or in performing DPD.

Although illustrated as a single stage, the power amplifier 1113 can include one or more stages. Furthermore, the teachings herein are applicable to communication systems including multiple power amplifiers.

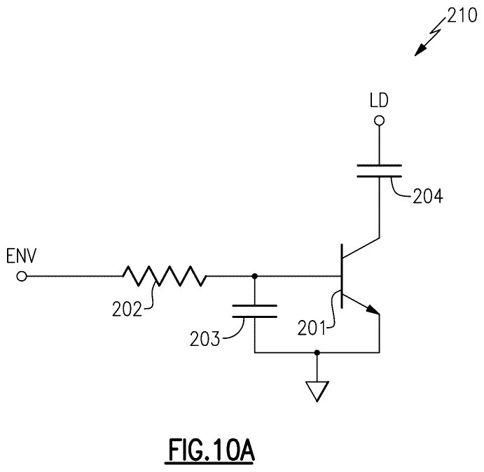

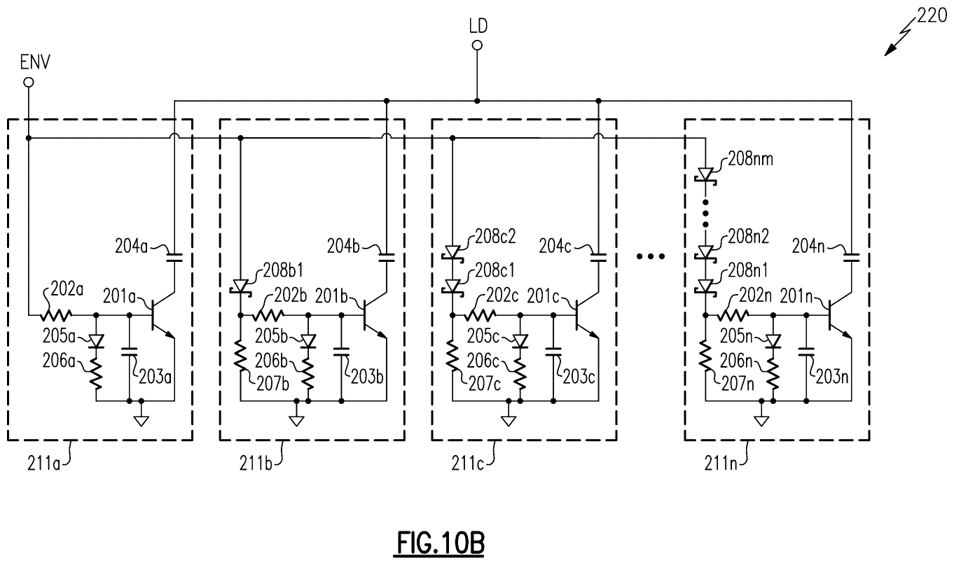

FIG. 10A is a schematic diagram of one embodiment of a controllable capacitor 210 for a load modulated power amplifier. The controllable capacitor can form part of any of the load modulators described herein. The controllable capacitor 210 includes a bipolar transistor 201 (for instance, a heterojunction bipolar transistor or HBT), a base resistor 202, a base capacitor 203, and a load capacitor 204. The base of the bipolar transistor 201 is controlled by an envelope signal ENV (received from an envelope tracker through the base resistor 202), while an emitter of the bipolar transistor 201 is grounded. The load capacitor 204 is coupled between a collector of the bipolar transistor 201 and a load terminal LD for loading a power amplifier (for instance, by serving as a termination capacitor to an output balun that is driven by the power amplifier). The base capacitor 203 is connected between the base of the bipolar transistor 201 and ground.

The bipolar transistor 201 operates as a variable resistor with the highest load line achieved when the envelope signal ENV is low and with the lowest load line achieved when the envelope signal ENV is high. The lowest loss is achieved at the highest load line, which is beneficial for modulated efficiency of a high PAPR waveform.

FIG. 10B is a schematic diagram of another embodiment of a controllable capacitor 220 for a load modulated power amplifier. The controllable capacitor 220 can form part of any of the load modulators described herein. The controllable capacitor 220 includes a plurality of controllable capacitor cells 211a, 211b, 211c, . . . 211n that are connected in parallel with one another between a load terminal LD (for loading a power amplifier) and ground.

As shown in FIG. 10B, the controllable capacitor cell 211a includes a bipolar transistor 201a, a base resistor 202a, a base capacitor 203a, a load capacitor 204a, a clamping diode 205a, and a clamping resistor 206a. The base of the bipolar transistor 201a is controlled by an envelope signal ENV received through the base resistor 202a, while an emitter of the bipolar transistor 201a is grounded. The load capacitor 204a is coupled between a collector of the bipolar transistor 201a and the load terminal LD. The base capacitor 203a is connected between the base of the bipolar transistor 201a and ground. Additionally, the clamping diode 205a and the clamping resistor 206a are connected in series between the base of the bipolar transistor 201a and ground, with the capacitor 203a in parallel with the series combination of the clamping diode 205a and the clamping resistor 206a.

With continuing reference to FIG. 10B, the controllable capacitor cell 211b includes a bipolar transistor 201b, a base resistor 202b, a base capacitor 203b, a load capacitor 204b, a clamping diode 205b, a clamping resistor 206b, a diode-biasing resistor 207b and a Schottky diode 208b1. Additionally, the controllable capacitor cell 211c includes a bipolar transistor 201c, a base resistor 202c, a base capacitor 203c, a load capacitor 204c, a clamping diode 205c, a clamping resistor 206c, a diode-biasing resistor 207c, and Schottky diodes 208c1 and 208c2. Furthermore, the controllable capacitor cell 211n includes a bipolar transistor 201n, a base resistor 202n, a base capacitor 203n, a load capacitor 204n, a clamping diode 205n, a clamping resistor 206n, a diode-biasing resistor 207n, and Schottky diodes 208n1, 208n2, . . . 208nm.

Although four controllable capacitor cells are depicted, any number of controllable capacitor cells can be included. As shown in FIG. 10B, each additional controllable capacitor cell includes an additional Schottky diode in comparison to the prior controllable capacitor.

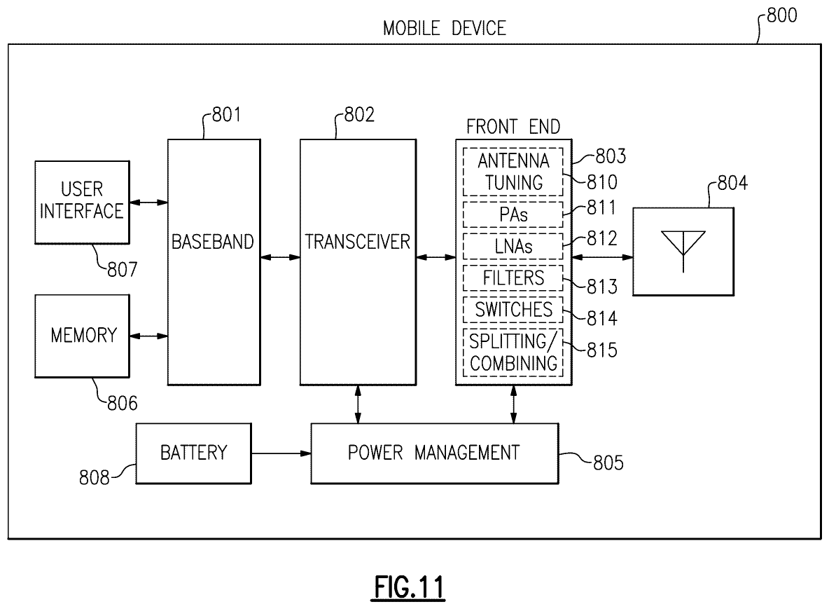

FIG. 11 is a schematic diagram of one embodiment of a mobile device 800. The mobile device 800 includes a baseband system 801, a transceiver 802, a front end system 803, antennas 804, a power management system 805, a memory 806, a user interface 807, and a battery 808. Depending on the embodiment, the mobile device 800 of FIG. 11 can implement any of the load modulators of FIG. 1-4B or 10A-10B (e.g., in the front end 803), the system 600 of FIG. 6A (e.g., in the front end 803 and/or the transceiver 802) or any of the components thereof, the phase modulator 650 of FIG. 6B (e.g., in the transceiver 802), and the communication system 1130 of FIG. 9 (e.g., in the front end 803 and/or the transceiver 802).

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 11 as the transceiver 802. In one example, separate components (for instance, separate circuits or dies) can be provided for handling certain types of RF signals.

The front end system 803 aids in conditioning signals transmitted to and/or received from the antennas 804. In the illustrated embodiment, the front end system 803 includes antenna tuning circuitry 810, power amplifiers (PAS) 811, low noise amplifiers (LNAs) 812, filters 813, switches 814, and signal splitting/combining circuitry 815. However, other implementations are possible.

For example, the front end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

At least one of the power amplifiers 811 is implemented as a load modulated power amplifier in accordance with the teachings herein. Although the mobile device 800 illustrates one embodiment of a communication system that can be implemented with one or more load modulated power amplifiers, the teachings herein are applicable to a wide range of systems. Accordingly, other implementations are possible.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 11, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 11, the power management system 805 receives a battery voltage from the battery 808. The battery 808 can be any suitable battery for use in the mobile device 800, including, for example, a lithium-ion battery.

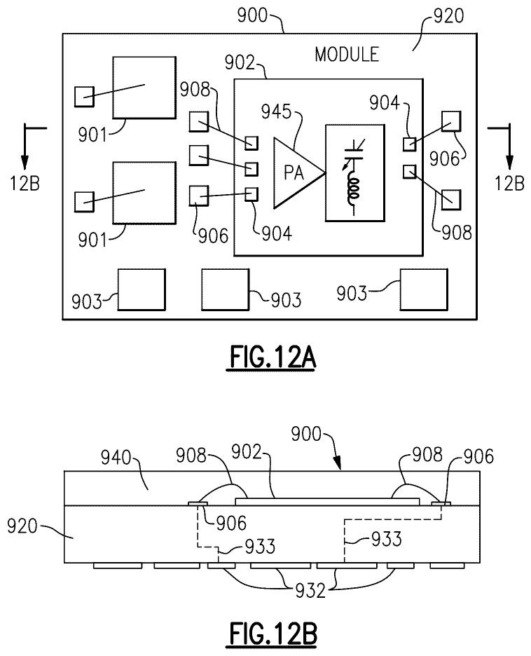

FIG. 12A is a schematic diagram of one embodiment of a packaged module 900. FIG. 12B is a schematic diagram of a cross-section of the packaged module 900 of FIG. 12A taken along the lines 12B-12B. Depending on the embodiment, the packaged module 900 of FIGS. 12A-12B can implement any of the load modulators of FIG. 1-4B or 10A-10B, some or all of the system 600 of FIG. 6A, the phase modulator 650 of FIG. 6B, and some or all of the communication system 1130 of FIG. 9.

The packaged module 900 includes radio frequency components 901, a semiconductor die 902, surface mount devices 903, wirebonds 908, a package substrate 920, and an encapsulation structure 940. The package substrate 920 includes pads 906 formed from conductors disposed therein. Additionally, the semiconductor die 902 includes pins or pads 904, and the wirebonds 908 have been used to connect the pads 904 of the die 902 to the pads 906 of the package substrate 920. The module 900 can be a front end module for example. In some embodiments, the module 900 can include one or more microprocessors, and the module 900 can implement a baseband processor or transceiver or portions thereof, for example.

The semiconductor die 902 includes a load modulated power amplifier 945, which can be implemented in accordance with any of the embodiments herein.

The packaging substrate 920 can be configured to receive a plurality of components such as radio frequency components 901, the semiconductor die 902 and the surface mount devices 903, which can include, for example, surface mount capacitors and/or inductors. In one implementation, the radio frequency components 901 include integrated passive devices (IPDs).

As shown in FIG. 12B, the packaged module 900 is shown to include a plurality of contact pads 932 disposed on the side of the packaged module 900 opposite the side used to mount the semiconductor die 902. Configuring the packaged module 900 in this manner can aid in connecting the packaged module 900 to a circuit board, such as a phone board of a mobile device. The example contact pads 932 can be configured to provide radio frequency signals, bias signals, and/or power (for example, a power supply voltage and ground) to the semiconductor die 902 and/or other components. As shown in FIG. 12B, the electrical connections between the contact pads 932 and the semiconductor die 902 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A mobile device comprising:
a baseband processor configured to provide a modulated digital signal;
one or more processors configured to apply digital pre-distortion and phase compensation to the modulated digital signal to generate a compensated digital signal;
a radio frequency modulator configured to convert the compensated digital signal to a radio frequency signal; and
a load modulated power amplifier configured to amplify the radio frequency signal.

2. The mobile device of claim 1 wherein the digital pre-distortion is based at least in part on a feedback signal corresponding to the amplified radio frequency signal.

3. The mobile device of claim 2 wherein the phase compensation is applied following the digital pre-distortion.

4. The mobile device of claim 1 further comprising a memory storing values used by the one or more processors to control the phase compensation.

5. The mobile device of claim 1 wherein the load modulated power amplifier includes a controllable load impedance coupled to an output of the load modulated power amplifier, the controllable load impedance adjustable via a load modulation control signal.

6. The mobile device of claim 5 wherein the controllable load impedance includes a controllable capacitor controlled by the load modulation control signal and an output balun having a first winding coupled to the output of the load modulated power amplifier and a second winding coupled to the controllable capacitor.

7. The mobile device of claim 6 wherein the load modulation control signal includes an envelope signal.

8. The mobile device of claim 7 further including a shaping circuit configured to shape the envelope signal based on calibration data.

9. A load modulated power amplifier system comprising:
one or more processors configured to apply digital pre-distortion and phase compensation to modulated digital signals to generate a compensated digital signal;
a radio frequency modulator configured to convert the compensated digital signal to a radio frequency signal; and
a load modulated power amplifier configured to receive a radio frequency signal and provide an amplified radio frequency signal.

10. The load modulated power amplifier system of claim 9 wherein the digital pre-distortion is based at least in part on a feedback signal corresponding to the amplified radio frequency signal.

11. The load modulated power amplifier system of claim 10 wherein the phase compensation is applied following the digital pre-distortion.

12. The load modulated power amplifier system of claim 9 further comprising a memory storing values used by the one or more processors to control the phase compensation.

13. The load modulated power amplifier system of claim 9 wherein the load modulated power amplifier includes a controllable load impedance coupled to an output of the load modulated power amplifier, the controllable load impedance adjustable via a load modulation control signal.

14. The load modulated power amplifier system of claim 13 wherein the controllable load impedance includes a controllable capacitor controlled by the load modulation control signal and an output balun having a first winding coupled to the output and a second winding coupled to the controllable capacitor.

15. The load modulated power amplifier system of claim 13 wherein the load modulation control signal includes an envelope signal.

16. The load modulated power amplifier system of claim 15 further including a shaping circuit configured to shape the envelope signal based on calibration data.

17. A method of amplification in a mobile device, the method comprising:
with one or more processors, applying digital pre-distortion and phase compensation to a modulated digital signal;
converting the digitally pre-distorted and phase compensated digital signal to a radio frequency signal; and
amplifying the radio frequency signal with a load modulated power amplifier to generate a load modulated amplified radio frequency signal.

18. The method of claim 17 further comprising using values accessed from a lookup table in memory to control the phase compensation.

19. The method of claim 17 further comprising adjusting a controllable load impedance coupled to an output of the load modulated power amplifier.

20. The method of claim 17 further comprising receiving a feedback signal corresponding to the load modulated amplified radio frequency signal, and applying the digital pre-distortion based on at least the feedback signal.
